(19) United States
(12) Patent Application Publication
(10) Pub. No.: US 2014/0224426 A1
(43) Pub. Date: Aug. 14, 2014

(54) SUBSTRATE SUPPORT UNIT AND PLASMA ETCHING APPARATUS HAVING THE SAME

(71) Applicant: SAMSUNG ELECTRONICS CO., LTD., Suwon-si (KR)

(72) Inventors: Tae Gon KIM, Seoul (KR); Kyung Hyun HAN, Hwaseong-si (KR); Yun Kwang JEON, Seoul (KR)

(73) Assignee: SAMSUNG ELECTRONICS CO., LTD., Suwon-si (KR)

(21) Appl. No.: 14/168,258

(22) Filed: Jan. 30, 2014

(30) Foreign Application Priority Data
Feb. 13, 2013 (KR) 10-2013-0015331

(51) Int. Cl. H01L 21/02

(52) U.S. Cl. CPC H01L 21/02002
USPC 156/345.51

(57) ABSTRACT

A substrate support unit of an etching process chamber includes a substrate support portion configured to support a substrate, a cathode under the substrate support portion, the cathode including an upper surface portion under the substrate support portion, the upper surface portion being smaller than a size of the substrate, and a step portion positioned a step downward from an edge portion of the upper surface portion, and a focus ring at an edge portion of the substrate, the focus ring being on the step portion and encompassing a side wall of the step portion and an edge portion of the substrate, the focus ring being configured to make a uniform distribution of an electric field on the substrate.

### CROSS-REFERENCE TO RELATED APPLICATION

Korean Patent Application No. 10-2013-0015331, filed on Feb. 13, 2013, in the Korean Intellectual Property Office, and entitled: “Substrate Support Unit and Plasma Etching Apparatus Having the Same,” is incorporated by reference herein in its entirety.

### BACKGROUND

1. Field

Embodiments relate to a substrate support unit and a plasma etching apparatus having the substrate support unit, and more particularly, to a substrate support unit capable of uniformly etching a substrate by making a uniform distribution of an electric field on the substrate, and a plasma etching apparatus having the substrate support unit.

2. Description of the Related Art

In general, when forming a pattern of a semiconductor wafer, a plasma etching apparatus for etching a wafer using plasma generated between a pair of electrodes is used to perform a high precision etch process. The plasma etching apparatus may be used to form an electrically conductive film for wiring on a substrate, e.g., a semiconductor wafer, an LCD substrate, etc. The plasma etching apparatus may include a process chamber for defining a space where an etch process using plasma is performed. The process chamber is provided with an upper electrode and a lower electrode for applying radio frequency (RF) power.

A substrate, e.g., a semiconductor wafer, may be arranged above the lower electrode. A reaction gas is supplied to the inside of the process chamber and RF power is applied to the upper and lower electrodes, thereby plasmarizing, i.e., ionizing, the reaction gas. The plasmarized, i.e., ionized, reaction gas is moved toward the lower electrode by self-bias potential of the substrate to etch the conductive film on the substrate. In order to increase yield of a substrate that is a process target of the plasma etching apparatus, the uniformity of an electric field on a substrate to an edge thereof is important.

### SUMMARY

Embodiments provide a substrate support unit with a uniform electric field distribution and a uniform plasma distribution on a substrate, thereby improving uniformity of an etching rate of the substrate, and a plasma etching apparatus having the substrate support unit.

According to an aspect of embodiments, there is provided a substrate support unit of an etching process chamber using plasma, the substrate support unit comprising a substrate support portion configured to support a substrate, a cathode under the substrate support portion, the cathode including an upper surface portion under the substrate support portion, the upper surface portion being smaller than a size of the substrate, and a step portion positioned a step downward from an edge portion of the upper surface portion, and a focus ring at an edge portion of the substrate, the focus ring being on the step portion and encompassing a side wall of the step portion and an edge portion of the substrate, the focus ring being configured to make a uniform distribution of an electric field on the substrate.

The focus ring may include a first ring member including a conductive material and having an inner wall contacting the side wall of the step portion and an outer wall extending outside the edge portion of the substrate, and a second ring member including a dielectric material and being positioned above the first ring member to contact the edge portion of the substrate.

The first ring member may include a first inclined portion that is inclined from an upper portion of inner wall of the first ring member toward a lower portion of the outer wall of the first ring member, and the second ring member may include a second inclined portion that is inclined in correspondence with a shape of the first inclined portion to contact and support the first inclined portion.

The first ring member may include a first curved portion that is convex from an upper portion of the inner wall of the first ring member toward a lower portion of the outer wall of the first ring member, and the second ring member may include a second curved portion that is concave in correspondence with a shape of the first curved portion to contact and support the first curved portion.

The focus ring may include a third ring member contacting the side wall of the step portion and extending outwardly from the edge portion of the substrate, the third ring member including a plurality of dielectrics having different permittivity and different electric conductivity and being continuously arranged on the step portion contacting each other, and a fourth ring member provided above the third ring member to contact the edge portion of the substrate, the fourth ring member being a dielectric.

The third ring member may further include an inner ring having an inner wall contacting the side wall of the step portion, and an outer ring having an inner wall contacting an outer wall of the inner ring, in which permittivity of the inner ring is smaller than that of the outer ring and electric conductivity of the inner ring is greater than that of the outer ring.

The substrate support unit may further include a cover ring that contacts the outer walls of the focus ring and the cathode, the cover ring being a dielectric and encompassing the focus ring and the cathode.

The substrate support portion may be an electrostatic chuck.

According to another aspect of embodiments, there is provided a plasma etching apparatus including a process chamber for performing an etching process using plasma, and a substrate support unit in an interior of a process chamber the substrate support unit including a substrate support portion configured to support a substrate, a cathode under the substrate support portion, the cathode including an upper surface portion under the substrate support portion to, the upper surface portion being smaller than a size of the substrate, and a step portion positioned a step downward from an edge portion of the upper surface portion, and a focus ring at an edge portion of the substrate, the focus ring being on the step portion and encompassing a side wall of the step portion and an edge portion of the substrate, the focus ring being configured to make a uniform distribution of an electric field on the substrate.

The focus ring may include a first ring member including a conductive material and having an inner wall contacting the side wall of the step portion and an outer wall extending outside the edge portion of the substrate, and a second ring member including a dielectric material and being positioned above the first ring member to contact the edge portion of the substrate.

The first ring member may include a first inclined portion that is inclined from an upper portion of the inner wall of the first ring member toward a lower portion of the outer wall of the first ring member, and the second ring member may include a second inclined portion that is inclined in correspondence with a shape of the first inclined portion to contact and support the first inclined portion.

The first ring member may include a first curved portion that is convex from an upper portion of the inner wall of the first ring member toward a lower portion of the outer wall of the first ring member, and the second ring member may include a second curved portion that is concave in correspondence with a shape of the first curved portion to contact and support the first curved portion.

The focus ring may include a third ring member contacting the side wall of the step portion and extending outwardly from the edge portion of the substrate, the third ring member including a plurality of dielectrics having different permittivity and different electric conductivity and being continuously arranged on the step portion contacting each other, and a fourth ring member provided above the third ring member to contact the edge portion of the substrate, the fourth ring member being a dielectric.

The third ring member may further include an inner ring having an inner wall contacting the side wall of the step portion, and an outer ring having an inner wall contacting an outer wall of the inner ring, in which permittivity of the inner ring is smaller than that of the outer ring and electric conductivity of the inner ring is greater than that of the outer ring.

The plasma etching apparatus may further include a gas supply unit for supplying a reaction gas to the interior of the process chamber, the gas supply unit including a gas distribution unit provided in the interior of the process chamber and arranged to face the substrate support unit, and a gas supply unit provided at one side of the process chamber and supplying the reaction gas to the gas distribution unit.

The plasma etching apparatus may further include an upper electrode arranged above the gas distribution unit and forming a buffer space with the gas distribution unit, and a radio frequency power supply unit provided at one side of the process chamber and supplying radio frequency power to the upper electrode to plasmarize the reaction gas in the interior of the process chamber, in which the cathode is a lower electrode that is an opposing electrode forming a pair with the upper electrode.

According to yet another aspect of embodiments, there is provided a substrate support unit of an etching process chamber using plasma, the substrate support unit including a cathode including an upper surface portion and a step portion relative to the upper surface portion, the step portion being lower than and peripheral to the upper surface portion, a substrate support portion on the upper surface portion of the cathode, the substrate support portion being configured to support a substrate, and the substrate being larger than the upper surface portion of the cathode, and a focus ring on the step portion of the cathode, the focus ring overlapping a side wall of the step portion and an edge of the substrate.

The focus ring may include a first ring member and a second ring member, the first ring member including a conductive material fitting into a right angle of the step portion and extending from an edge of the substrate support portion to an outermost sidewall of the cathode, and the second ring member including a dielectric material covering the first ring member.

The second ring member may be directly on and flush against the first ring member.

A portion of the second ring member may be directly on and flush against the substrate, the first ring member being completely covered by a flat surface defined by the substrate and the portion of the second ring member.

### BRIEF DESCRIPTION OF THE DRAWINGS

Features will become apparent to those of ordinary skill in the art by describing in detail exemplary embodiments with reference to the attached drawings, in which:

FIG. 1 schematically illustrates a plasma etching apparatus according to an exemplary embodiment;

FIG. 2 illustrates an enlarged cross-sectional view of a substrate support unit according to an exemplary embodiment;

FIG. 3 illustrates a cross-sectional view of a change in the distribution of an electric field by the substrate support unit, according to an exemplary embodiment;

FIG. 4 schematically illustrates a plasma etching apparatus according to another exemplary embodiment;

FIG. 5 illustrates an enlarged cross-sectional view of a substrate support unit according to another exemplary embodiment;

FIG. 6 illustrates a cross-sectional view of a change in the distribution of an electric field by the substrate support unit, according to another exemplary embodiment;

FIG. 7 schematically illustrates a plasma etching apparatus according to another exemplary embodiment;

FIG. 8 illustrates an enlarged cross-sectional view of a substrate support unit according to another exemplary embodiment; and

FIG. 9 illustrates a cross-sectional view of a change in the distribution of an electric field by the substrate support unit, according to another exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. Like reference numerals in the drawings denote like elements.

In the following exemplary embodiments, a substrate may include, e.g., a substrate for a flat panel display panel, e.g., a liquid crystal display panel and a plasma display panel, a substrate for a hard disk, and/or a substrate for an electronic device, e.g., a semiconductor wafer.

A plasma etching apparatus 100 according to an exemplary embodiment is described below.

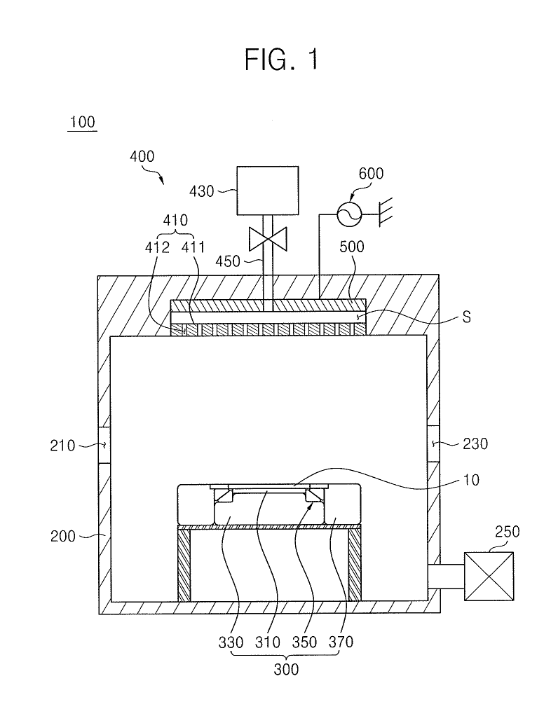

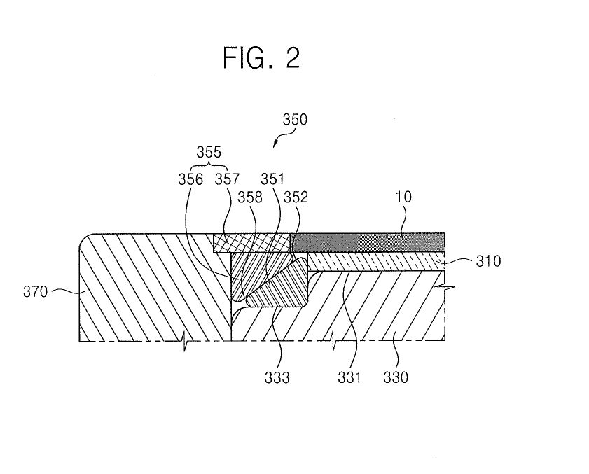

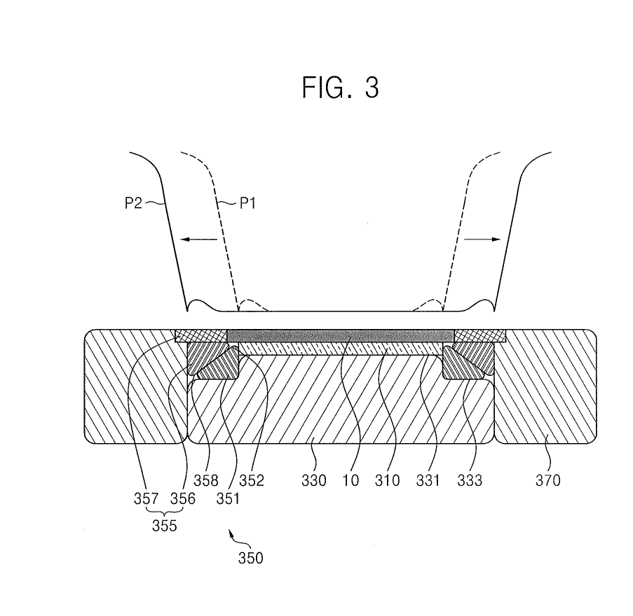

FIG. 1 schematically illustrates the plasma etching apparatus 100 according to an exemplary embodiment. FIG. 2 illustrates an enlarged cross-sectional view of a substrate support unit 300 according to an exemplary embodiment. FIG. 3 illustrates a cross-sectional view of a change in the distribution of an electric field by the substrate support unit 300, according to an exemplary embodiment.

Referring to FIGS. 1 to 3, the plasma etching apparatus 100 according to the present exemplary embodiment may include a process chamber 200, in which an etching process using plasma is performed on a substrate 10, a gas supply unit 400 for supplying a reaction gas to an interior of the process chamber 200, a radio frequency (RF) power supply unit 600 provided at one side of the process chamber 200 and supplying RF power to plasmarize, i.e., ionize, the reaction gas in the interior of the process chamber 200, and the substrate support unit 300 arranged inside the process chamber 200 and supporting the substrate 10.

Referring to FIG. 1, the process chamber 200 provides a space where an etching process is performed on the substrate 10. In the present exemplary embodiment, the process chamber 200 is roughly formed in a cylindrical shape, but embodiments are not limited thereto. The shape of the process chamber 200 may vary according to the type and shape of the substrate 10.

The interior of the process chamber 200 is hermetically sealed and is maintained in a vacuum state during the etching process of the substrate 10. To this end, a vacuum pump 250 is provided in a lower portion of the process chamber 200. When the vacuum pump 250 generates a vacuum pressure, the interior of the process chamber 200 may be maintained in a high vacuum state.

A substrate inlet 210, through which the substrate 10 enters into the interior of the process chamber 200, may be formed at one side of the process chamber 200. A substrate outlet 230, through which the substrate 10 is carried out from the process chamber 200, may be formed at one, e.g., other, side of the process chamber 200. A separate gate valve (not shown) may be provided in each of the substrate inlet 210 and the substrate outlet 230.

For example, when an etching process is performed on the substrate 10, a gate valve provided in the substrate inlet 210 is opened and the substrate 10 is carried into the interior of the process chamber 200 by a transfer robot (not shown) through the substrate inlet 210 so as to be placed on a substrate support portion 310 that is described later. After the transfer robot retreats out of the process chamber 200, the gate valve is closed. Then, the interior of the process chamber 200 is maintained in a vacuum state by the vacuum pump 250. When the etching process on the substrate 10 is completed, the gate valve in the substrate outlet 230 is opened and the substrate 10 is carried out from the process chamber 200 by the transfer robot through the substrate outlet 230.

Referring to FIG. 1, in the present exemplary embodiment, the gas supply unit 400 supplies the reaction gas for an etching process performed on the substrate 10 to the interior of the process chamber 200. The gas supply unit 400 includes a gas distribution unit 410 arranged in the process chamber 200 to face the substrate support unit 300, a gas supply unit 430 provided at one side of the process chamber 200 to supply the reaction gas to the gas distribution unit 410, and a gas supply pipe 450 having one end connected to the gas supply unit 430 and the other end connected to the gas distribution unit 410 so as to supply the reaction gas to the gas distribution unit 410 from the gas supply unit 430.

The gas distribution unit 410 is arranged in an upper inner portion of the process chamber 200 to face the substrate support unit 300 and discharges a plasmarized reaction gas toward the substrate 10. As illustrated in FIG. 1, in the present exemplary embodiment, the gas distribution unit 410 may be arranged to face the substrate 10 and may include a shower head 411 having a plurality of through holes 412. However, embodiments are not limited thereto and any structure capable of discharging the plasmarized reaction gas toward the substrate 10, e.g., an injection nozzle (not shown) that may inject the plasmarized reaction gas, may be employed.

The gas supply unit 430 may be provided in the upper portion of the process chamber 200 and supplies the reaction gas to the gas distribution unit 410. The reaction gas may include an inert gas having no chemical activity, e.g., helium (He), neon (Ne), argon (Ar), etc. and a fluorocarbon based gas, e.g., tetrafluoride (CF₄). The reaction gas is supplied from the gas supply unit 430 to the gas distribution unit 410 via the gas supply pipe 450.

Referring to FIG. 1, the reaction gas supplied by the gas supply unit 400 is plasmarized in the interior of the process chamber 200 and etches the substrate 10. In the present exemplary embodiment, in order to plasmarize the reaction gas in the process chamber 200, an upper electrode 500 is arranged above the gas distribution unit 410 in the interior of the process chamber 200. A buffer space S, where the reaction gas is plasmarized, is formed between the gas distribution unit 410 and the upper electrode 500.

A lower electrode, i.e., an opposing electrode forming a pair with the upper electrode 500, may be arranged under the substrate 10. In the present exemplary embodiment, a cathode 330 arranged under the substrate support portion 310 defines the lower electrode, which is described later. The RF power supply unit 600 supplies RF power directly to the upper electrode 500. Thus, as illustrated in FIG. 1, the reaction gas supplied to the shower head 411 is plasmarized in the buffer space S, and the plasmarized reaction gas is discharged toward the substrate 10 via the through holes 412 of the shower head 411.

Referring to FIG. 2, in the present exemplary embodiment, the substrate support unit 300 is provided in the interior of the process chamber 200 and supports the substrate 10. The substrate support unit 300 may include the substrate support portion 310 supporting the substrate 10, the cathode 330 under the substrate support portion 310, a focus ring 350 encompassing edge portions of the cathode 330 and the substrate 10, and a cover ring 370 encompassing the focus ring 350 and the cathode 330.

The substrate support portion 310 is arranged in the interior of the process chamber 200 to support the substrate 10 in a level state. In the present exemplary embodiment, the substrate support portion 310 is configured with an electrostatic chuck (ESC) for supporting, e.g., electrostatically gripping, the substrate 10 at a level state. In the ESC 310, an electrode (not shown) is interposed between dielectrics (not shown). When a DC power is applied to the electrode, the ESC 310 sucks, i.e., holds by suction, the substrate 10 due to the Coulomb force.

When an etching process is performed on the substrate 10, the substrate 10 is carried by the transfer robot to pass through the substrate inlet 210 so as to be placed on an upper surface of the ESC 310. When the etching process on the substrate 10 is completed, the transfer robot carries the substrate 10 placed on the upper surface of the ESC 310 through the substrate outlet 230 for a subsequent process.

The cathode 330 is arranged under the substrate support portion 310. The cathode 330 forms the lower electrode and generates an electric field in the interior of the process chamber 200 forming a pair with the upper electrode 500. In the present exemplary embodiment, the cathode 330 includes an upper surface portion 331 arranged under, e.g., and in contact with, the substrate support portion 310, and formed to be smaller than the size of the substrate 10. Further, the cathode 330 includes a step portion 333 formed to have a step downward from an edge portion of the upper surface portion 331.

When the electric field generated by the upper electrode 500 and the cathode 330, that is the lower electrode, is irregularly distributed on the substrate 10, irregularity in an etching rate of the substrate 10 may increase. That is, in the present exemplary embodiment, since the upper surface portion 331 of the cathode 330 is smaller, e.g., has a smaller width along a horizontal direction, than the substrate 10, and the cathode 330 has a step portion 333 formed downward from the upper surface portion 331, the electric field is concentrated at a position corresponding to the step portion 333 of the cathode 330. Thus, the electric field may be irregularly distributed on the substrate 10 that is placed on the substrate support portion 310.

In detail, as the size of the substrate 10 increases, e.g., to be larger than that of the cathode 330, the strength of an electric field at the edge portion of the substrate 10, e.g., at a position corresponding to the step portion 333 of the cathode 330, is greater than that of an electric field at a center portion of the substrate 10. Thus, irregularity in the distribution of an electric field may be generated. In other words, since electric charges are concentrated on the step portion 333 of the cathode 330, the electric field may be concentrated at the edge portion of the substrate 10, e.g., at a portion of the substrate 10 overlapping the step portion 333 rather than the upper surface portion 331.

Thus, in the present exemplary embodiment, when the size of the substrate 10 is larger than that of the cathode 330, the focus ring 350 is provided at the step portion 333 of the cathode 330 to prevent the irregularity of an electric field on the substrate 10, i.e., to prevent the concentration of an electric field at the edge portion of the substrate 10 that overlaps the step portion 333 of the cathode 330. In the present exemplary embodiment, the focus ring 350 allows the electric charges concentrated at the step portion 333 to move outside the edge portion of the substrate 10, thereby providing uniformity of an electric field on the substrate 10.

Referring to FIG. 2, in the present exemplary embodiment, the focus ring 350 includes a first ring member 351 formed of a conductive material and having an inner wall contacting a side wall of the step portion 333 and an outer wall extending outside the edge portion of the substrate 10, and a second ring member 355 that is a dielectric and provided above the first ring member 351 to contact the edge portion of the substrate 10.

The first ring member 351 is formed of a conductive metal material. The inner wall of the first ring member 351 contacts the side wall of the step portion 333 of the cathode 330 and the outer wall thereof extends outwardly from the edge portion of the substrate 10. For example, as illustrated in FIG. 3, the first ring member 351 may have a cross-section of a right-triangle, such that the right angle of the right triangle fits into a right angle defined by the step portion 333, and the hypotenuse of the right triangle extends from the edge portion of the substrate 10 toward an outermost sidewall of the cathode 330. Accordingly, the first ring member 351 moves the electric charges concentrated on the side wall of the step portion 333, e.g., a side wall of the step portion 333 extending from a side wall of the substrate support portion 310 and perpendicularly to the substrate 10, to the outside of the edge portion of the substrate, e.g., toward the outermost sidewall of the cathode 330.

A first inclined portion 352, i.e., the hypotenuse of the right triangle, inclined from an upper portion of the inner wall of the first ring member 351 contacting the side wall of the step portion 333 toward a lower portion of the outer wall thereof is formed on the first ring member 351. As the first inclined portion 352 extends from the inside of the edge portion of the substrate 10 to the outside thereof, the electric charges concentrated on the side wall of the step portion 333 of the cathode 330 may be uniformly distributed in a direction from the inside of the edge portion of the substrate 10 to the outside thereof.

As illustrated in FIG. 3, a graph indicating a distribution of an electric field is moved from P1 to P2 by the first ring member 351 formed of a conductive material and arranged at the step portion 333 of the cathode 330. In other words, the concentration of an electric field is moved from the edge portion of the substrate 10 to the outside of the edge portion of the substrate 10.

As described above, as the concentration of the electric field is moved outside the edge portion of the substrate 10 by the first ring member 351, intensity of plasma at the edge portion of the substrate 10 generated due to the concentration of an electric field may be reduced. Also, since uniformity of plasma is obtained throughout the entire surface of the substrate 10, uniformity in the etching rate of the substrate 10 may be improved.

The second ring member 355 is provided to prevent the first ring member 351 from being etched in the etching process of the substrate 10 using plasma. Accordingly, the second ring member 355 is formed of a dielectric material, e.g., a ceramic material.

The second ring member 355 is provided above the first ring member 351 to contact the edge portion of the substrate 10, so that the plasmarized reaction gas is prevented from reaching the first ring member 351. In other words, the second ring member 355 prevents the first ring member 351 from being etched by the plasmarized reaction gas.

A second inclined portion 358 is formed on the ring member 355 to contact and support the first inclined portion 352 of the first ring member 351. The second inclined portion 358 is formed to be inclined in correspondence with the shape of the first inclined portion 352, so as to closely contact the first inclined portion 352, e.g., the first and second inclined portions 352 and 358 may overlap each other and be flush against each other. Thus, a loss of contact of the inner wall of the first ring member 351 with the side wall of the step portion 333 may be prevented.

As illustrated in FIG. 2, the second ring member 355 may include a first sub-ring member 356 contacting an upper portion of the first ring member 351 and a second sub-ring member 357 provided above the first sub-ring member 356 to contact the edge portion of the substrate 10. The first sub-ring member 356 and the second sub-ring member 357 are also formed of a dielectric material, e.g., a ceramic material.

When the second ring member 355 is configured with the first sub-ring member 356 and the second sub-ring member 357, the second inclined portion 358 that contacts and supports the first inclined portion 352 is formed at one side of the first sub-ring member 356. The second sub-ring member 357 that closely, e.g., directly, contacts the, e.g., entire, edge portion of the substrate 10 prevents the plasmarized, i.e., ionized, reaction gas from reaching below the substrate 10, i.e., from reaching the first ring member 351 between the substrate 10 and the cathode 330.

The cover ring 370 also prevents the plasmarized reaction gas from contacting the first ring member 351. As illustrated in FIG. 2, the cover ring 370 is arranged to closely, e.g., directly, contact the, e.g., entire, outer wall of the cathode 330 and the outer walls of the first and second sub-ring members 356 and 357 of the second ring member 355 so as to prevent the plasmarized reaction gas from reaching the first ring member 351. Also, the cover ring 370 that closely contacts the outer walls of the first and second sub-ring members 356 and 357 contacts and supports the first and second sub-ring members 356 and 357.

A process of etching the substrate 10 using the plasma etching apparatus 100 according to an exemplary embodiment is described below.

First, the gate valve provided in the substrate inlet 210 of the process chamber 200 may be opened, and the substrate 10 may be carried into the interior of the process chamber 200 by the transfer robot and may be placed on the substrate support portion 310. Then, the transfer robot retreats out of the process chamber 200, and the gate valve may be closed. The interior of the process chamber 200 is maintained in a vacuum state by the vacuum pump 250 provided at one side of the process chamber 200.

In a state in which interior of the process chamber 200 is maintained in a vacuum state, the reaction gas is supplied by the gas supply unit 430 into the buffer space S provided between the gas distribution unit 410 and the upper electrode 500. Then, the RF power supply unit 600 supplies RF power to the upper electrode 500. As the RF power is applied to the upper electrode 500, an electric field is formed between the upper electrode 500 and the cathode 330, i.e., the lower electrode.

The reaction gas supplied into the electric field is plasmarized, i.e., ionized, and the substrate 10 is etched by the plasmarized reaction gas. After the etching process of the substrate 10 is completed, the supply of the RF power and the reaction gas is stopped and the substrate 10 is carried out from the process chamber 200 by the transfer robot through the substrate outlet 230 for a subsequent process.

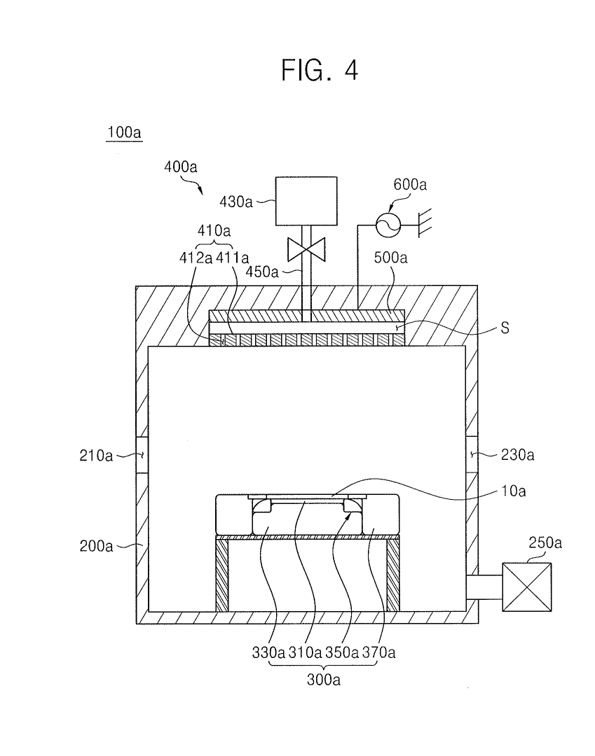

A plasma etching apparatus 100a according to another exemplary embodiment is described below with reference to FIGS. 4-6.

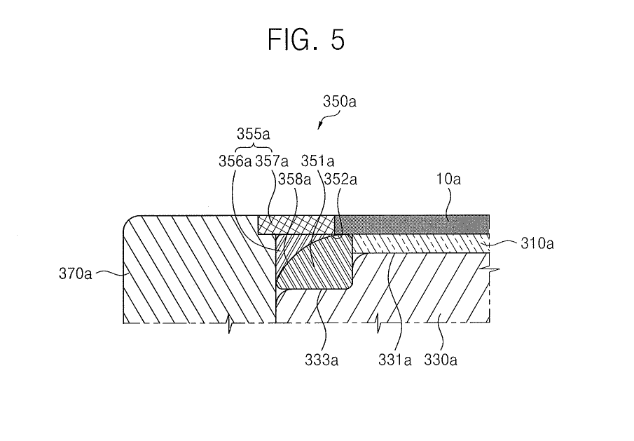

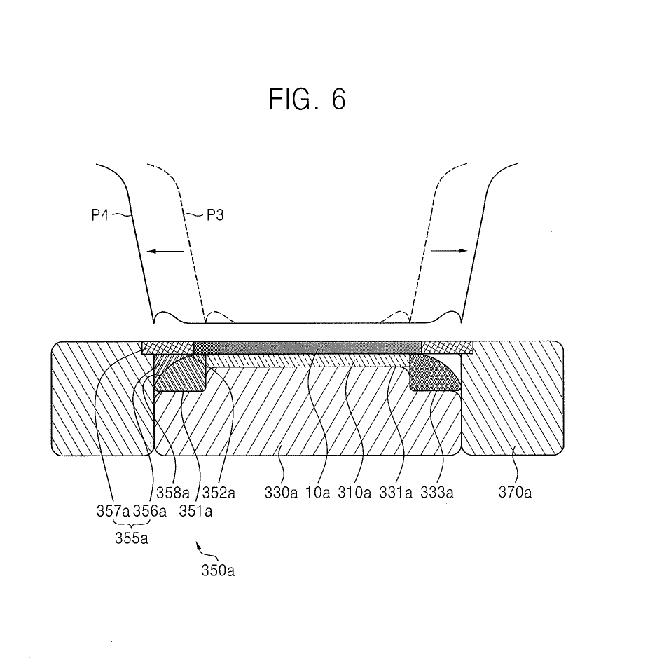

FIG. 4 schematically illustrates the plasma etching apparatus 100a according to an exemplary embodiment. FIG. 5 illustrates an enlarged cross-sectional view of a substrate support unit 300a according to another exemplary embodiment. FIG. 6 illustrates a cross-sectional view of a change in the distribution of an electric field by the substrate support unit 300a, according to another exemplary embodiment.

Referring to FIGS. 4 to 6, the plasma etching apparatus 100a according to the present exemplary embodiment may include a process chamber 200a in which an etching process using plasma is performed on a substrate 10a, a gas supply unit 400a for supplying a reaction gas to the interior of the process chamber 200a, a radio frequency (RF) power supply unit 600a provided at one side of the process chamber 200a and supplying RF power to plasmarize the reaction gas in the interior of the process chamber 200a, and the substrate support unit 300a arranged inside the process chamber 200a and supporting the substrate 10a.

Since the process chamber 200a, the gas supply unit 400a, and the RF power supply unit 600a according to the present exemplary embodiment are respectively the same as the process chamber 200, the gas supply unit 400, and the RF power supply unit 600 according to the above-described exemplary embodiment, detailed descriptions thereof will be omitted. The substrate support unit 300a that is different from the above-described exemplary embodiment will be mainly discussed in detail.

Referring to FIG. 5, in the present exemplary embodiment, the substrate support unit 300a is provided in the interior of the process chamber 200a and supports the substrate 10a. The substrate support unit 300a includes a substrate support portion 310a supporting the substrate 10a, a cathode 330a that is a lower electrode arranged under the substrate support portion 310a, a focus ring 350a encompassing edge portions of the cathode 330a and the substrate 10a, and a cover ring 370a encompassing the focus ring 350a and the cathode 330a.

The substrate support portion 310a is arranged in the interior of the process chamber 200a to support the substrate 10a in a level state. In the present exemplary embodiment, the substrate support portion 310a is configured with an electrostatic chuck (ESC) for sucking the substrate 10a in a level state. In the ESC 310a, an electrode (not shown) is interposed between dielectrics (not shown). When a DC power is applied to the electrode, the ESC 310a sucks the substrate 10a due to the Coulomb force.

The cathode 330a is arranged under the substrate support portion 310a. The cathode 330a forms the lower electrode and generates an electric field in the interior of the process chamber 200a forming a pair with an upper electrode 500a. In the present exemplary embodiment, the cathode 330a includes an upper surface portion 331a arranged under the substrate support portion 310a and formed to be smaller than the size of the substrate 10a and a step portion 333a formed to have a step downward from an edge portion of the upper surface portion 331a.

When the electric field generated by the upper electrode 500a and the cathode 330a that is the lower electrode is irregularly distributed on the substrate 10a, irregularity in an etching rate of the 10a may increase in the etching process of the substrate 10a using plasma. In the present exemplary embodiment, since the upper surface portion 331a of the cathode 330a is smaller than the substrate 10a and the cathode 330a has a step portion 333a formed downward from the upper surface portion 331a, the electric field is concentrated on a position corresponding to the step portion 333a of the cathode 330a and thus the electric field may be irregularly distributed on the substrate 10a that is placed on the substrate support portion 310a.

Particularly, as the size of the substrate 10a increases, if the size of the substrate 10a is larger than that of the cathode 330a, the strength of an electric field at the edge portion of the substrate 10a at a position corresponding to the step portion 333a of the cathode 330a is greater than that of an electric field at a center portion of the substrate 10a and thus irregularity in the distribution of an electric field may be generated. In other words, since electric charges are concentrated on the step portion 333a of the cathode 330a, the electric field may be concentrated on the edge portion of the substrate 10a.

Thus, in the present exemplary embodiment, when the size of the substrate 10a is larger than that of the cathode 330a, the focus ring 350a is provided at the step portion 333a of the cathode 330a to prevent the irregularity of an electric field on the substrate 10a, i.e., the concentration of an electric field at the edge portion of the substrate 10a, which is generated by the step portion 333a of the cathode 330a. In the present exemplary embodiment, the focus ring 350a allows the electric charges concentrated on the step portion 333a to move outside the edge portion of the substrate 10a and thus uniformity of an electric field on the substrate 10a may be obtained.

Referring to FIG. 5, in the present exemplary embodiment, the focus ring 350a includes a first ring member 351a formed of a conductive material and having an inner wall contacting a side wall of the step portion 333a and an outer wall extending outside the edge portion of the substrate 10a, and a second ring member 355a that is a dielectric and provided above the first ring member 351a to contact the edge portion of the substrate 10a.

The first ring member 351a is formed of a conductive metal material. The inner wall of the first ring member 351a contacts the side wall of the step portion 333a of the cathode 330a and the outer wall thereof extends outwardly from the edge portion of the substrate 10a. Accordingly, the first ring member 351a moves the electric charges concentrated on the side wall of the step portion 333a of the cathode 330a to the outside of the edge portion of the substrate 10a.

A first curved portion 352a that is convex toward the second ring member 355a is formed on the first ring member 351a. As the first curved portion 352a extends from the inside of the edge portion of the substrate 10a to the outside thereof, the electric charges concentrated on the side wall of the step portion 333a of the cathode 330a may be uniformly distributed in a direction from the inside of the edge portion of the substrate 10a to the outside thereof.

As illustrated in FIG. 6, a graph indicating a distribution of an electric field is moved from P3 to P4 by the first ring member 351a formed of a conductive material and arranged at the step portion 333a of the cathode 330a. In other words, the concentration of an electric field is moved from the edge portion of the substrate 10a to the outside of the edge portion of the substrate 10a.

As described above, as the concentration of an electric field is moved outside the edge portion of the substrate 10a by the first ring member 351a, intensity of plasma at the edge portion of the substrate 10a generated due to the concentration of an electric field may be reduced. Also, since uniformity of plasma is obtained throughout the entire surface of the substrate 10a, uniformity in the etching rate of the substrate 10a may be improved.

A second ring member 355a is provided to prevent the first ring member 351a from being etched in the etching process of the substrate 10a using plasma. Accordingly, the second ring member 355a is formed of a dielectric, e.g., a ceramic material.

The second ring member 355a is provided above the first ring member 351a to contact the edge portion of the substrate 10a so that the plasmarized reaction gas is prevented from reaching the first ring member 351a. In other words, the second ring member 355a prevents the first ring member 351a from being etched by the plasmarized reaction gas.

A second curved portion 358a is formed on the ring member 355a to contact and support the first curved portion 352a of the first ring member 351a. The second curved portion 358a is formed to be concave in correspondence with the shape of the first curved portion 352a to closely contact the first curved portion 352a so that a loss of contact of the inner wall of the first ring member 351a with the side wall of the step portion 333a is prevented.

As illustrated in FIG. 5, the second ring member 355a may include a first sub-ring member 356a contacting an upper portion of the first ring member 351a and a second sub-ring member 357a provided above the first sub-ring member 356a to contact the edge portion of the substrate 10a. The first sub-ring member 356a and the second sub-ring member 357a are also formed of a dielectric, e.g., a ceramic material.

When the second ring member 355a is configured with the first sub-ring member 356 and the second sub-ring member 357, the second curved portion 358a that contacts and supports the first curved portion 352a is formed at one side of the first sub-ring member 356a. The second sub-ring member 357a that closely contacts the edge portion of the substrate 10a prevents the plasmarized reaction gas from reaching the first ring member 351a.

The cover ring 370a also prevents the plasmarized reaction gas from contacting the first ring member 351a. As illustrated in FIG. 2, the cover ring 370a is arranged to closely contact the outer wall of the cathode 330a and the outer walls of the first and second sub-ring members 356a and 357a of the second ring member 355a so as to prevent the plasmarized reaction gas from reaching the first ring member 351a. Also, the cover ring 370a that closely contacts the outer walls of the first and second sub-ring members 356a and 357a contacts and supports the first and second sub-ring members 356a and 357a.

A plasma etching apparatus 100b according to another exemplary embodiment of is described below.

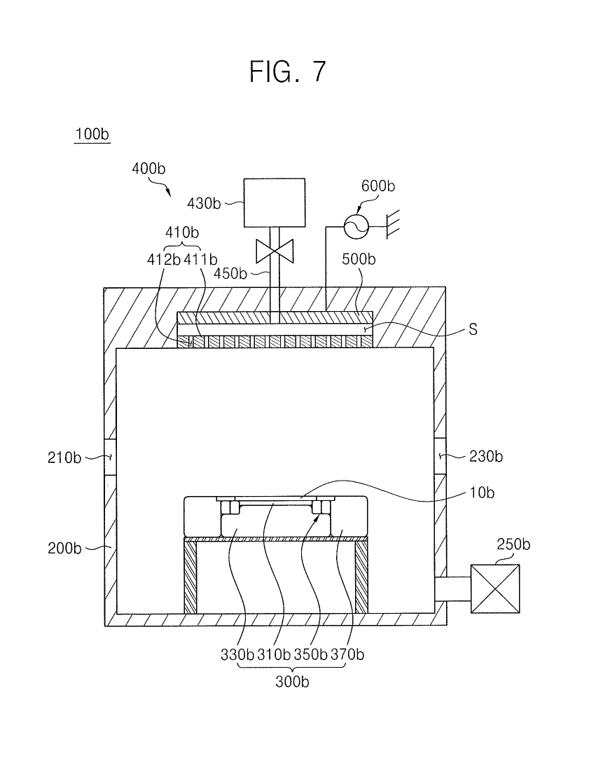

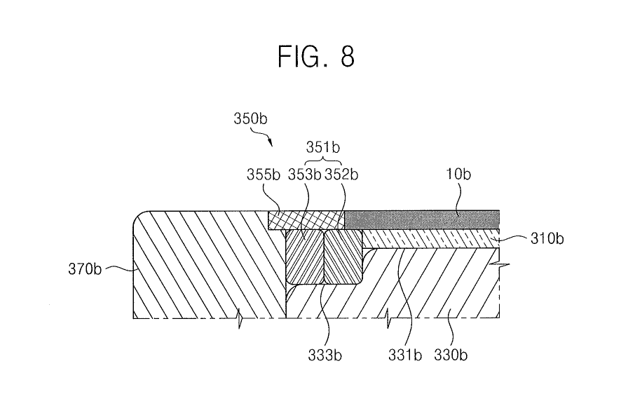

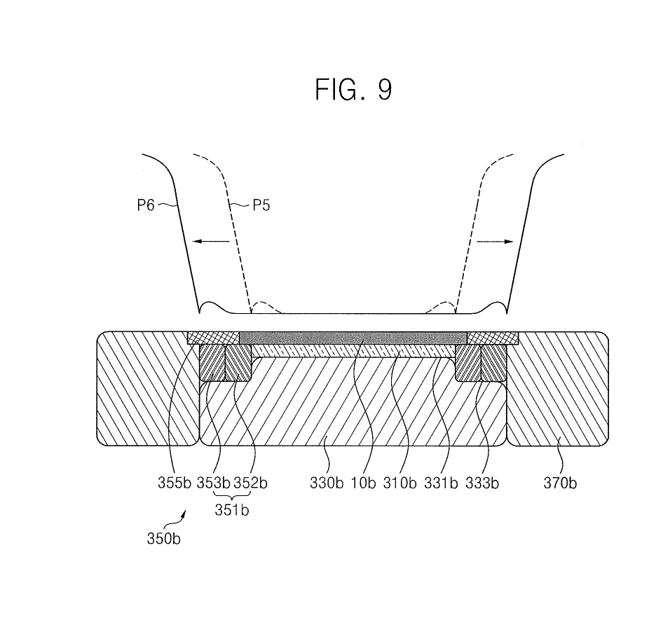

FIG. 7 schematically illustrates the plasma etching apparatus 100b according to an exemplary embodiment. FIG. 8 illustrates an enlarged cross-sectional view of a substrate support unit 300b according to another exemplary embodiment. FIG. 9 illustrates a cross-sectional of a change in the distribution of an electric field by the substrate support unit 300b, according to another exemplary embodiment.

Referring to FIGS. 7 to 9, the plasma etching apparatus 100b according to the present exemplary embodiment includes a process chamber 200b in which an etching process using plasma is performed on a substrate 10b, a gas supply unit 400b for supplying a reaction gas to the interior of the process chamber 200b, a radio frequency (RF) power supply unit 600b provided at one side of the process chamber 200b and supplying RF power to plasmarize the reaction gas in the interior of the process chamber 200b, and the substrate support unit 300b arranged inside the process chamber 200b and supporting the substrate 10b.

Since the process chamber 200b, the gas supply unit 400b, and the RF power supply unit 600b according to the present exemplary embodiment are respectively the same as the process chamber 200, the gas supply unit 400, and the RF power supply unit 600 according to the above-described exemplary embodiment, detailed descriptions thereof will be omitted. The substrate support unit 300b that is different from the above-described exemplary embodiment will be mainly discussed in detail.

Referring to FIG. 8, in the present exemplary embodiment, the substrate support unit 300b is provided in the interior of the process chamber 200b and supports the substrate 10b. The substrate support unit 300b includes a substrate support portion 310b supporting the substrate 10b, a cathode 330b that is a lower electrode arranged under the substrate support portion 310b, a focus ring 350b encompassing edge portions of the cathode 330b and the substrate 10b, and a cover ring 370b encompassing the focus ring 350b and the cathode 330b.

The substrate support portion 310b is arranged in the interior of the process chamber 200b to support the substrate 10b in a level state. In the present exemplary embodiment, the substrate support portion 310b is configured with an electrostatic chuck (ESC) for sucking the substrate 10b in a level state. In the ESC 310b, an electrode (not shown) is interposed between dielectrics (not shown). When a DC power is applied to the electrode, the ESC 310b sucks the substrate 10b due to the Coulomb force.

The cathode 330b is arranged under the substrate support portion 310b. The cathode 330b forms the lower electrode and generates an electric field in the interior of the process chamber 200b forming a pair with an upper electrode 500b. In the present exemplary embodiment, the cathode 330b includes an upper surface portion 331b arranged under the substrate support portion 310b and formed to be smaller than the size of the substrate 10b and a step portion 333b formed to have a step downward from an edge portion of the upper surface portion 331b.

When the electric field generated by the upper electrode 500b and the cathode 330b that is the lower electrode is irregularly distributed on the substrate 10b, irregularity in an etching rate of the 10b may increase in the etching process of the substrate 10b using plasma. In the present exemplary embodiment, since the upper surface portion 331b of the cathode 330b is smaller than the substrate 10b and the cathode 330b has a step portion 333b formed downward from the upper surface portion 331b, the electric field is concentrated on a position corresponding to the step portion 333b of the cathode 330b and thus the electric field may be irregularly distributed on the substrate 10b that is placed on the substrate support portion 310b.

Particularly, as the size of the substrate 10b increases recently, if the size of the substrate 10b is larger than that of the cathode 330b, the strength of an electric field at the edge portion of the substrate 10b at a position corresponding to the step portion 333b of the cathode 330b is greater than that of an electric field at a center portion of the substrate 10b and thus irregularity in the distribution of an electric field may be generated. In other words, since electric charges are concentrated on the step portion 333b of the cathode 330b, the electric field may be concentrated on the edge portion of the substrate 10b.

Thus, in the present exemplary embodiment, when the size of the substrate 10b is larger than that of the cathode 330b, the focus ring 350b is provided at the step portion 333b of the cathode 330b to prevent the irregularity of an electric field on the substrate 10b, that is, the concentration of an electric field at the edge portion of the substrate 10b, which is generated by the step portion 333b of the cathode 330b. In the present exemplary embodiment, the focus ring 350b allows the electric charges concentrated on the step portion 333b to move outside the edge portion of the substrate 10b and thus uniformity of an electric field on the substrate 10b may be obtained.

Referring to FIG. 8, in the present exemplary embodiment, the focus ring 350b includes a third ring member 351b formed of a conductive material and having an inner wall contacting a side wall of the step portion 333b and an outer wall extending outside the edge portion of the substrate 10b, and a fourth ring member 355b that is a dielectric and provided above the third ring member 351b to contact the edge portion of the substrate 10b.

The third ring member 351b is formed of a conductive metal material. The inner wall of the third ring member 351b contacts the side wall of the step portion 333b of the cathode 330b and the outer wall thereof extends outwardly from the edge portion of the substrate 10b. Accordingly, the third ring member 351b moves the electric charges concentrated on the side wall of the step portion 333b of the cathode 330b to the outside of the edge portion of the substrate 10b.

As illustrated in FIG. 8, the third ring member 351b includes an inner ring 352b whose inner wall contacts the side wall of the step portion 333b and an outer ring 353b whose inner wall contacts the outer wall of the inner ring 352b. The inner ring 352b and the outer ring 353b are formed to have different permittivity and different electric conductivity.

In order to move the electric charges concentrated on the side wall of the step portion 333b outside the edge portion of the substrate 10b, the permittivity of the inner ring 352b is smaller than that of the outer ring 353b and the electric conductivity of the inner ring 352b is greater than that of the outer ting 353b.

As described above, as a plurality of dielectrics having different permittivity and different electric conductivity are arranged continuously to contact the step portion 333b, the electric charges concentrated on the side wall of the step portion 333b of the cathode 330b may be uniformly distributed in a direction from the inside of the edge portion of the substrate 10b to the outside thereof.

As illustrated in FIG. 9, a graph indicating a distribution of an electric field is moved from P5 to P6 by the third ring member 351b arranged at the step portion 333b of the cathode 330b. In other words, the concentration of an electric field is moved from the edge portion of the substrate 10b to the outside of the edge portion of the substrate 10b.

As described above, as the concentration of an electric field is moved outside the edge portion of the substrate 10b by the third ring member 351b, intensity of plasma at the edge portion of the substrate 10b generated due to the concentration of an electric field may be reduced. Also, since uniformity of plasma is obtained throughout the entire surface of the substrate 10b, uniformity in the etching rate of the substrate 10b may be improved.

A fourth ring member 355b is provided to prevent the third ring member 351b from being etched in the etching process of the substrate 10b using plasma. Accordingly, the fourth ring member 355b is formed of a dielectric such as ceramic.

The fourth ring member 355b is provided above the third ring member 351b to contact the edge portion of the substrate 10b so that the plasmarized reaction gas is prevented from reaching the third ring member 351b. In other words, the fourth ring member 355b prevents the third ring member 351b from being etched by the plasmarized reaction gas.

The cover ring 370b also prevents the plasmarized reaction gas from contacting the third ring member 351b. As illustrated in FIG. 8, the cover ring 370b is arranged to closely contact the outer wall of the cathode 330b, the outer wall of the outer ring 353b forming the third ring member 351b, and the outer wall of the fourth ring member 355b so as to prevent the plasmarized reaction gas from reaching the third ring member 351b. Also, the cover ring 370b that closely contacts the outer walls of the outer ring 353b and the fourth ring member 355b contacts and supports the outer ring 353b and the fourth ring member 355b.

As described above, according to embodiments, a focus ring is provided at a step portion of a cathode, so that a distribution of an electric field and plasma on the substrate are uniform. Thus, the uniformity in the etching rate of the substrate may be improved.

In contrast, when a substrate is larger than a lower electrode, i.e., when an edge of a substrate protrudes a predetermined length beyond an edge of an upper surface of the lower electrode, and is positioned on a substrate support without a focus ring, an electric field concentrates at the edge of the substrate corresponding to the edge of the upper surface of the lower electrode. Accordingly, irregularity of an etching rate of a substrate increases due to an irregular plasma distribution on the substrate.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A substrate support unit of an etching process chamber using plasma, the substrate support unit comprising:
a substrate support portion configured to support a substrate;
a cathode under the substrate support portion, the cathode including:
an upper surface portion under the substrate support portion, the upper surface portion being smaller than a size of the substrate, and
a step portion positioned a step downward from an edge portion of the upper surface portion; and
a focus ring at an edge portion of the substrate, the focus ring being on the step portion and encompassing a side wall of the step portion and an edge portion of the substrate, the focus ring being configured to make a uniform distribution of an electric field on the substrate.

2. The substrate support unit as claimed in claim 1, wherein the focus ring includes:
a first ring member including a conductive material and having an inner wall contacting the side wall of the step portion and an outer wall extending outside the edge portion of the substrate; and
a second ring member including a dielectric material and being positioned above the first ring member to contact the edge portion of the substrate.

3. The substrate support unit as claimed in claim 2, wherein:
the first ring member comprises a first inclined portion that is inclined from an upper portion of inner wall of the first ring member toward a lower portion of the outer wall of the first ring member, and
the second ring member comprises a second inclined portion that is inclined in correspondence with a shape of the first inclined portion to contact and support the first inclined portion.

4. The substrate support unit as claimed in claim 2, wherein:
the first ring member comprises a first curved portion that is convex from an upper portion of the inner wall of the first ring member toward a lower portion of the outer wall of the first ring member, and
the second ring member comprises a second curved portion that is concave in correspondence with a shape of the first curved portion to contact and support the first curved portion.

5. The substrate support unit as claimed in claim 1, wherein the focus ring comprises:
a third ring member contacting the side wall of the step portion and extending outwardly from the edge portion of the substrate, the third ring member including a plurality of dielectrics having different permittivity and different electric conductivity and being continuously arranged on the step portion contacting each other; and
a fourth ring member provided above the third ring member to contact the edge portion of the substrate, the fourth ring member being a dielectric.

6. The substrate support unit as claimed in claim 5, wherein the third ring member further includes:
an inner ring having an inner wall contacting the side wall of the step portion; and
an outer ring having an inner wall contacting an outer wall of the inner ring,
wherein permittivity of the inner ring is smaller than that of the outer ring and electric conductivity of the inner ring is greater than that of the outer ring.

7. The substrate support unit as claimed in claim 1, further comprising a cover ring that contacts the outer walls of the focus ring and the cathode, the cover ring being a dielectric and encompassing the focus ring and the cathode.

8. The substrate support unit as claimed in claim 1, wherein the substrate support portion is an electrostatic chuck.

9. A plasma etching apparatus, comprising:
a process chamber for performing an etching process using plasma; and
a substrate support unit in an interior of the process chamber, the substrate support unit including:
a substrate support portion configured to support a substrate,
a cathode under the substrate support portion, the cathode including:
an upper surface portion under the substrate support portion, the upper surface portion being smaller than a size of the substrate, and
a step portion positioned a step downward from an edge portion of the upper surface portion, and
a focus ring at an edge portion of the substrate, the focus ring being on the step portion and encompassing a side wall of the step portion and an edge portion of the substrate, the focus ring being configured to make a uniform distribution of an electric field on the substrate.

10. The plasma etching apparatus as claimed in claim 9, wherein the focus ring includes:
a first ring member including a conductive material and having an inner wall contacting the side wall of the step portion and an outer wall extending outside the edge portion of the substrate; and
a second ring member including a dielectric material and being positioned above the first ring member to contact the edge portion of the substrate.

11. The plasma etching apparatus as claimed in claim 10, wherein:
the first ring member comprises a first inclined portion that is inclined from an upper portion of the inner wall of the first ring member toward a lower portion of the outer wall of the first ring member, and
the second ring member comprises a second inclined portion that is inclined in correspondence with a shape of the first inclined portion to contact and support the first inclined portion.

12. The plasma etching apparatus as claimed in claim 10, wherein:
the first ring member comprises a first curved portion that is convex from an upper portion of the inner wall of the first ring member toward a lower portion of the outer wall of the first ring member, and
the second ring member comprises a second curved portion that is concave in correspondence with a shape of the first curved portion to contact and support the first curved portion.

13. The plasma etching apparatus as claimed in claim 9, wherein the focus ring comprises:
a third ring member contacting the side wall of the step portion and extending outwardly from the edge portion of the substrate, the third ring member including a plurality of dielectrics having different permittivity and different electric conductivity and being continuously arranged on the step portion contacting each other; and
a fourth ring member provided above the third ring member to contact the edge portion of the substrate, the fourth ring member being a dielectric.

14. The plasma etching apparatus as claimed in claim 13, wherein the third ring member further includes:
an inner ring having an inner wall contacting the side wall of the step portion; and
an outer ring having an inner wall contacting an outer wall of the inner ring,
wherein permittivity of the inner ring is smaller than that of the outer ring and electric conductivity of the inner ring is greater than that of the outer ring.

15. The plasma etching apparatus as claimed in claim 9, further comprising a gas supply unit for supplying a reaction gas to the interior of the process chamber, the gas supply unit including:
a gas distribution unit provided in the interior of the process chamber and arranged to face the substrate support unit; and
a gas supply unit provided at one side of the process chamber and supplying the reaction gas to the gas distribution unit.

16. The plasma etching apparatus as claimed in claim 15, further comprising:
an upper electrode arranged above the gas distribution unit and forming a buffer space with the gas distribution unit; and
a radio frequency power supply unit provided at one side of the process chamber and supplying radio frequency power to the upper electrode to plasmarize the reaction gas in the interior of the process chamber,
wherein the cathode is a lower electrode that is an opposing electrode forming a pair with the upper electrode.

17. A substrate support unit of an etching process chamber using plasma, the substrate support unit comprising:
a cathode including an upper surface portion and a step portion relative to the upper surface portion, the step portion being lower than and peripheral to the upper surface portion;
a substrate support portion on the upper surface portion of the cathode, the substrate support portion being configured to support a substrate, and the substrate being larger than the upper surface portion of the cathode; and
a focus ring on the step portion of the cathode, the focus ring overlapping a side wall of the step portion and an edge of the substrate.

18. The substrate support unit as claimed in claim 17, wherein the focus ring includes a first ring member and a second ring member, the first ring member including a conductive material fitting into a right angle of the step portion and extending from an edge of the substrate support portion to an outermost sidewall of the cathode, and the second ring member including a dielectric material covering the first ring member.

19. The substrate support unit as claimed in claim 18, wherein the second ring member is directly on and flush against the first ring member.

20. The substrate support unit as claimed in claim 19, wherein a portion of the second ring member is directly on and flush against the substrate, the first ring member being completely covered by a flat surface defined by the substrate and the portion of the second ring member.
